(19) United States
(12) Patent Application Publication
(10) Pub. No.: US 2018/0261428 A1
(43) Pub. Date: Sep. 13, 2018

(54) ION SOURCE SPUTTERING

(71) Applicant: GENCOA LTD, Liverpool (GB)

(72) Inventor: Victor Bellido-Gonzalez, Liverpool (GB)

(21) Appl. No.: 15/759,966

(22) PCT Filed: Oct. 11, 2016
(86) PCT No.: PCT/IB2016/056069

§ 371 Date: Mar. 14, 2018

(30) Foreign Application Priority Data
Sep. 14, 2015 (GB) 1516171.4

(51) Int. Cl. H01J 37/32; H01J 37/34

(52) U.S. Cl. CPC H01J 37/32027; H01J 37/32045; H01J 37/32422; H01J 37/3444; H01J 37/342; H01J 37/3438; H01J 37/32568

(57) ABSTRACT

An ion source comprising: an electrode; a counter electrode; means for generating an electrical potential between the electrode and counter-electrode; one or more magnets arranged, in use, to confine a plasma generated around the electrode upon application of the said electrical potential; and an aperture in the counter-electrode through which ions from the said plasma can escape; characterized in that: the means for generating an electrical potential between the electrode and counter electrode comprises a DC signal generator that is: electrically connected to the electrode and the counter-electrode; adapted, in use, to apply a baseline DC potential to the electrode and the counter-electrode with the DC potential at the electrode being positive relative to the DC potential at the counter electrode; and adapted, in use, to apply a sequence of DC pulses superimposed onto the baseline DC potential.

### TECHNICAL FIELD

This invention relates to generation and control of ions for the purpose of sputtering, ion treatment, process control and coating in very confined spaces. This invention also relates to the use of present device of the invention as sensors for feedback plasma or non-plasma process control. Feedback control systems using this type of device as a sensor; manufacturing process and methods which use these devices and or sensors, and materials and components processed by the present invention are also part of the invention.

This invention also relates to the control of plasma processes as for example magnetron sputtering of a material in argon (or other inert gas mixture) or inert gases (such as helium) plus reactive gases such as nitrogen, oxygen, hydrocarbon gases, vapours such as water, siloxanes (e.g. hexamethyldisilioxane), nebulised components such as high vapour pressure monomers mists, or other mixtures in any kind of phase (solid, liquid, gas). This invention also relates to the use of sensors for feedback plasma or non-plasma process control; feedback control systems using this type of sensor; manufacturing process and methods which use these sensors, and materials and components of the present invention.

### BACKGROUND ART

Many industrial vacuum coating applications depend on the process control of species near, or in, a plasma environment. One of those is the Reactive Magnetron Sputtering process for which typically an optical signal with spectroscopic information (intensity for a particular wavelength) or a voltage signal with target operation information is taken as a feedback [J. CHAPIN, C. R. CONDON, “Feedback Control for Vacuum Depositing Apparatus” U.S. Pat. No. 4,166,784-4 Sep. 1979]. For good process control, generally a good feedback system is required in which appropriate sensors feedback information related to the variation of the process.

One of the main problems in plasma technology is the limited number of sensors and their instability during the running of key plasma processes. Gas monitor devices [C. NOMINE, D. PIERREJEAN, US2006290925] [V. BELLIDO-GONZALEZ, D. MONAGHAN, B. DANIEL, GB2441582] offer the possibility of monitoring processes via a secondary plasma in order to control or monitor the main plasma or main chamber process. These devices' detection focus on the gas compositional mixture via spectral analysis of the secondary plasma. However, the excitation is typically restricted to the gas phase elements. Some of those control processes would benefit from having a reactive element local to the sensor. The present invention achieves this by bringing such type of elements from ion sputtering of an electrode which is part of the present invention.

In addition, the present invention, due to the miniaturisation ability, offers the possibility of using such devices for coating, plasma processing and ion treatment of very confined spaces, as those found in very small diameter and long tubes of a particle accelerator such as a synchrotron.

Further, many industrial vacuum coating applications depend on the process control of species near to, or in, a plasma environment. One of those is the Reactive Magnetron Sputtering process for which typically an optical signal with spectroscopic information (intensity for a particular wavelength) or a voltage signal with target operation information is taken as a feedback [J. CHAPIN, C. R. CONDON, “Feedback Control for Vacuum Depositing Apparatus” U.S. Pat. No. 4,166,784-4 Sep. 1979]. For good process control, generally a good feedback system is required in which appropriate sensors feedback information related to the variation of the process. One of the main problems in plasma technology is the limited number of sensors and their instability during the running of key plasma processes. Gas monitor devices [C. NOMINE, D. PIERREJEAN, US2006290925] [V. BELLIDO-GONZALEZ, D. MONAGHAN, B. DANIEL, GB2441582] offer the possibility of monitoring processes via a secondary plasma in order to control or monitor the main plasma or main chamber process. These devices detection focus on the gas compositional mixture via spectral analysis of the secondary plasma.

A feature of the invention is that it may offer the possibility of using remote sensor/secondary plasma with added sensitivity compared with the prior art by introducing selective elements that are not necessarily a part of the main plasma reactions and which are not necessarily in the gas phase. The present invention also provides a simple way of upscaling the use of these sensors for large area plasma coaters such as those used in glass coating technology.

### DISCLOSURE OF THE INVENTION

Various aspects of the invention are set forth in the appended claims.

A first aspect of the invention provides an ion source comprising: an electrode; a counter electrode; means for generating an electrical potential between the electrode and counter-electrode; one or more magnets arranged, in use, to confine a plasma generated around the electrode upon application of the said electrical potential; and an aperture in the counter-electrode through which ions from the said plasma can escape; characterised in that: the means for generating an electrical potential between the electrode and counter electrode comprises a DC signal generator that is: electrically connected to the electrode and the counter-electrode; adapted, in use, to apply a baseline DC potential to the electrode and the counter-electrode with the DC potential at the electrode being positive relative to the DC potential at the counter electrode; and adapted, in use, to apply a sequence of DC pulses superimposed onto the baseline DC potential.

Another aspect of the invention provides a method of using an ion source comprising: an electrode; a counter electrode; a DC signal generator electrically connected to the electrode and the counter-electrode; one or more magnets arranged, in use, to confine, in use, a plasma generated around the electrode; and an aperture in the counter-electrode through which ions from the said plasma can escape; the method being characterised by the steps of: generating a baseline electrical potential between the electrode and counter-electrode, with the DC potential at the electrode being positive relative to the DC potential at the counter electrode; and applying a sequence of DC pulses superimposed onto the baseline DC potential.

Suitably, the baseline DC potential is between 0 and 0.5 kV.

Preferably, the baseline DC potential is substantially 0.3 kV, which has been found to be about optimal for a copper sputtering process.

Suitably, the peak voltage of the DC pulses is between 1 and 3 Kv.

Preferably, the peak voltage of the DC pulses is substantially 2 kV, which has been found to be about optimal for a copper sputtering process.

The or each DC pulse may comprise an “overshoot” at its leading or trailing edge, which overshoot may increase the maxima of each respective pulse to greater than 2 kV (for example, up to 2.5 kV); and/or which may decrease the minima of each respective pulse below the baseline DC potential (for example, to 0 kV, or even as low as −1 kV), but this does not detract from the invention and is within the scope of the claims.

Suitably, the duration of the DC pulses is less than 100 ms. Preferably, the duration of the DC pulses is substantially 80 [symbol] s, which has been found to be about optimal for a copper sputtering process.

The DC signal generator is adapted, in use, to apply a sequence of DC pulses (33) superimposed onto the baseline DC potential. The sequence is suitably a periodic sequence, and more preferably a regular periodic sequence.

Suitably, the DC pulses are delivered at 5-10 ms intervals, i.e. they have a pulse repetition rate/periodicity of between 5 and 10 ms. Preferably, the DC pulses are delivered at substantially 8.2 ms intervals (122 Hz), i.e. a pulse repetition rate/periodicity of about 8.2 us, which has been found to be about optimal for a copper sputtering process.

In many embodiments of the invention, the DC pulse maximum potential, periodicity ad duration will be substantially fixed, or at least be constant on-average. However, in other embodiments, the pulse parameters may be varied from pulse-to-pulse, or according to a predetermined change from one set of parameters to another.

The power of each pulse can be fixed or variable, depending on the application. In certain embodiments, the pulse power varies in voltage and/or current from pulse to pulse depending on the dynamic plasma discharge conditions although. In certain embodiments of the invention, the pulse power can be considered relatively constant, on-average.

The invention differs from the prior art insofar as the DC signal generator is adapted to apply a baseline DC potential as well as a sequence of DC pulses superimposed onto the baseline DC potential; as opposed to the prior art in which only a substantially constant DC potential is applied to the electrode and counter-electrode (cf. GB2441582); or in which an AC potential is applied to the electrode and counter-electrode (cf. GB2441582).

The advantage of using a baseline DC potential and a sequence of DC pulses (33) superimposed onto the baseline DC potential is that the transient DC pulses superimposed on the baseline DC potential induce an electrical field, which accelerates the ions of the plasma towards the counter-electrode. However, because the counter-electrode has an aperture in it, some of the ions are able to escape, for example towards a workpiece or substrate to be coated by a vacuum deposition process.

The invention therefore partially, or completely obviates the need for a secondary electrical or magnetic field to cause the ions generated by the ion source to be ejected.

By controlling the electrical field and the pulsed conditions of the energy of impact of the ions can be controlled, making sputtering of the wall of the electrode possible. The plasma itself will contain not only the elements of the gas input or background, but also the elements of the solid counter-electrode.

Plasma emission can be collected and guided via components towards suitable spectroscopic analysis elements such as photomultiplier tubes, CCD spectrometers, photodiodes or any other suitable optical device.

Typically, the device would be connected to a sub-atmospheric pressure region. Different types plasma discharge 5 could be attained depending on pressure conditions as well as the pulsed power condition.

In certain embodiments of the invention, the counter-electrode has a shape, for example, a tapered profile, which forms an inclined surface. The shape of the counter-electrode may be configured such that it encourages sputtered material or ions to escape the plasma zone towards a region, for example, containing a substrate to be coated. In other words, the shape of the counter-electrode can be designed in such a way as to deflect the trajectories of ions or other sputtered material towards a substrate to coated.

Depending on the shape and configuration of the counter-electrode, the trajectories of ions or other sputtered material can be preferentially directed towards a substrate located in-line with the aperture, or in other cases, radially outwardly to impinge on a tubular substrate surrounding the ion source. In certain embodiments of the invention, the ion source can be configured to treat (e.g. ion etch) or coat (e.g. sputter coat) the interior surface of a tube by advancing the ion source axially along the interior of the tube.

The ion source may also comprise a feedback system, which controls the DC signal generator in response to the instantaneous performance of the ion source. This can be accomplished, in certain embodiments, by providing a spectroscopic analysis element, such as photomultiplier tubes, CCD spectrometers, photodiodes or any other suitable optical device, downstream of the aperture, and by measuring the optical properties of the plasma, calculating and providing input controls to adapt/control the parameters of the DC signal generator.

The ion source suitably comprises a feedback system adapted, in use, to control the DC signal generator in response to the instantaneous performance of the ion source, the feedback system comprising a spectroscopic analysis element being any one or more of the group comprising: a photomultiplier tube; a CCD spectrometer; and a photodiode—located downstream of the aperture, the spectroscopic analysis element being adapted, in use, to measure the optical properties of the plasma, the feedback system further comprising calculating means for calculating required changes to the parameters of the DC signal generator, and means for providing feedback input controls to adapt/control the parameters of the DC signal generator.

Suitably, the feedback system is configured to maintain the emissions of the ion source substantially constant.

The ion source is suitably used in an at least partially evacuated environment, and so the ion source may be sealingly connected to a low-pressure process chamber with its aperture registered with a corresponding aperture in, say, a side wall of the low-pressure process chamber.

Alternatively, the ion source may be disposed entirely within a low-pressure process chamber, for example, one defined by, or including, the interior surface of a tubular or hollow substrate to be internally treated or coated.

A vacuum pump may be provided to at least partially evacuate the low-pressure process chamber. Additionally, a gas feed may be provided, to introduce an inert, catalytic or reactive gas into the low-pressure process chamber.

The ion source may comprise a sensor marker in the plasma zone, the plasma zone being the region surrounding the electrode in which the plasma is generated, the sensor marker producing, in the presence of the plasma, an emission containing emissions of that material.

According to another aspect of the invention, there is provided a sputtering system, such as an ion source, comprising: an electrode; a counter electrode; means for generating an electrical potential between the electrode and counter-electrode; one or more magnets arranged, in use, to confine a plasma generated around the electrode upon application of the said electrical potential; and an aperture in the counter-electrode through which ions from the said plasma can escape; characterised by: a sensor marker in the plasma zone, the plasma zone being the region surrounding the electrode in which the plasma is generated, the sensor marker producing, in the presence of the plasma, an emission containing emissions of that material.

Suitably, the system further comprises an optical detector adapted, in use, to measure an optical characteristic of the plasma. The optical detector can be any one or more of the group comprising: an infrared detector; a visible light detector; an ultraviolet detector.

The detector is suitably a spectroscopic detector.

The detector is suitably configured, in use, to measure any one or more of the group comprising: an emission spectrum of the plasma; an absorption spectrum of the plasma; and a fluorescence spectrum of the plasma.

Suitably, the sensor marker comprises a tube, at least partially surrounding the electrode, manufactured from a material of a specified element.

Suitably, the sensor marker comprises a rod or plate adjacent the electrode, manufactured from a material of a specified element.

Suitably, the sensor marker comprises a gas, which gas is directed towards the electrode, the gas being a specified element.

The specified element, in the context of this disclosure, suitably interacts with the plasma thereby increasing the sensitivity of the signal is introduced by elements that are present in the sensor and that have a wider response to that compared of the main plasma or process area. The element of higher sensitivity response could be introduced in the secondary plasma area via a solid material containing the chemical element or by a gas that contains that element.

Another aspect of the invention provides, a new type of sensor that is applicable to plasma or non-plasma processes in order to provide a control or monitoring signal. Processes could be plasma processes such as reactive plasma processes or non-plasma processes such as Chemical Vapour Deposition (CVD).

The monitored signal could also be used for general process information or process decisions, for example the sensor could monitor outgassed components of flame or plasma treatment, vacuum plasma processes and atmospheric plasma processes as well. As an example, the sensor could monitor the water vapour content in a vessel before the system is considered to be in a good vacuum condition. As an example, the sensor could be used as an End-Point-Detection when the process continues into shut down or goes into the following step of the process routine. The use of these sensors also enables new processes and manufacturing methods and materials with good feedback control which have not been possible to manufacture previously due to limitations in current sensor technology.

The present invention is based on a sensor which provides stable and enhanced spectroscopic information (optical signal) despite process disturbances such as substrate movement and plasma drifts but which is sensitive to the total or partial pressure of gases and/or volatiles in the vacuum chamber and/or gas mixtures or volatile mixtures of inert or reactive components. The sensor monitors signals from this remote plasma generated by different species. These species have some degree of interacting in the main plasma process. The sensibility of the signal is introduced by elements that are present in the sensor and that have a wider response to that compared of the main plasma or process area. The element of higher sensitivity response could be introduced in the secondary plasma area via a solid material containing the chemical element or by a gas that contains that element. The sensor could sense via Infrared, Visible or UV emission, absorption or fluorescence signals from the activated species in the remote plasma. The signal could be taken as it is, monochromated, filtered (e.g. by a narrow band pass filter), spectroscopically treated (e.g. using a CCD spectrometer), or treated by any physical or numerical manipulation which would render a value that can be “monitored” hence create a reference for the process.

According to an aspect of the invention, a new type of ion source sputtering and sensor is provided that is applicable to plasma or non-plasma processes in order to provide a plasma process treat, ion bombard or coat. The present invention can also be used as a sensor for control or monitoring signal as the material that is being sputtered can selectively react with gas phase elements of a particular process. Processes could be plasma processes such as reactive plasma processes or non-plasma processes such as Chemical Vapour Deposition (CVD). The monitored signal could also be used for general process information or process decisions, for example the sensor could monitor outgassed components of flame or plasma treatment, vacuum plasma processes and atmospheric plasma processes as well. As an example, the sensor could monitor the water vapour content in a vessel before the system is considered to be in a good vacuum condition. As an example, the sensor could be used as an End-Point-Detection when the process continues into shut down or goes into the following step of the process routine. The use of these sensors also enables new processes and manufacturing methods and materials with good feedback control which have not been possible to manufacture previously due to limitations in current sensor technology.

The present invention is based on an essentially high intensity positive voltage pulse applied to an electrode which is essentially internal to the counter-electrode. A suitable magnetic field will allow the electrons to be retarded in arriving to the positive pulse, in that effect gas phase ionisation will take place. The voltage spike would produce a strong deflection of the electric field and the ions which have been generated by electron collision will be propelled out towards the walls of the counter-electrode. In the impact sputtering will take place.

By shaping the pulse, magnetic field, electrode geometry, gas phase components it is possible to use the device related to the present invention for different applications such as coating, plasma treatment of surfaces, internal surfaces coating and treatment, ion etching, reactive ion etching, PACVD.

In one of the embodiments of the present invention the device could provide stable and enhanced spectroscopic information (optical signal) despite process disturbances such as substrate movement and plasma drifts but which is sensitive to the total or partial pressure of gases and/or volatiles in the vacuum chamber and/or gas mixtures or volatile mixtures of inert or reactive components. The sensor monitors signals from this remote plasma generated by different species. These species have some degree of interacting in the main plasma process. The sensibility of the signal is introduced by elements that are present in the sensor and that have a wider response to that compared of the main plasma or process area. The element of higher sensitivity response could be introduced in the secondary plasma area via a solid material containing the chemical element or by a gas that contains that element. The sensor could sense via Infrared, Visible or UV emission, absorption or fluorescence signals from the activated species in the remote plasma. The signal could be taken as it is, monochromated, filtered (e.g. by a narrow band pass filter), spectroscopically treated (e.g. using a CCD spectrometer), or treated by any physical or numerical manipulation which would render a value that can be “monitored” hence create a reference for the process.

In another part of the present invention, this invention also relates to a feedback control system that uses this type of sensors as a signal feedback in order to generate an adequate response or actuation on a process system.

In another part of the present invention, this invention also relates to plasma or non-plasma processes that could use this type of sensors or could use a feedback control system or apparatus which uses this kind of sensor input in order to monitor the process or to introduce changes in the process conditions or to control the process progress.

In another part of the present invention, this invention also relates to manufacturing methods in which parts, components, devices in its totality or in part have undergone a process involving the use of this type of ion sputtering plasma treatment, coating deposition, ion etching or sensors, as for example coating of internal tubes and confined spaces, coating of glass, manufactured semiconductor devices, coated tools, etc.

In another part of the present invention, monitoring points could be established along a large area of process treatment which can give information on process and process mapping and could enable local actuation in different areas of the process.

This invention also relates to materials, components and devices manufactured by methods which use these ion sputtering devices.

### LIST OF FIGURES

The invention will be further described by way of example only with reference to the following figures in which:

FIGS. 1 and 2 are schematic cross-sections of known ion sources;

FIGS. 3 to 5 are schematic cross-sections of various embodiments of ion sources in accordance with the invention;

FIG. 6a is an example of a CCD spectra of a plasma generated by a known ion source;

FIG. 6b is an example of a CCD spectra of a plasma generated by an embodiment of an ion source in accordance with the invention;

FIG. 7a, is an oscilloscope voltage trace of a particular pulsed power and frequency applied to an ion source according to the invention;

FIG. 7b, is an oscilloscope voltage trace of a particular pulsed power in accordance with eh invention;

FIGS. 8 to 10 are schematic cross-sections of various embodiments of ion sources in accordance with the invention further comprising a sensor marker and sensor;

FIG. 11 is an example of spectra that can be generated by a device from the present invention; and

FIG. 12 an example of spectra where in addition to gas lines, some metal emission lines from a jacket such as that described in FIG. 8 can be seen.

### DETAILED DESCRIPTION

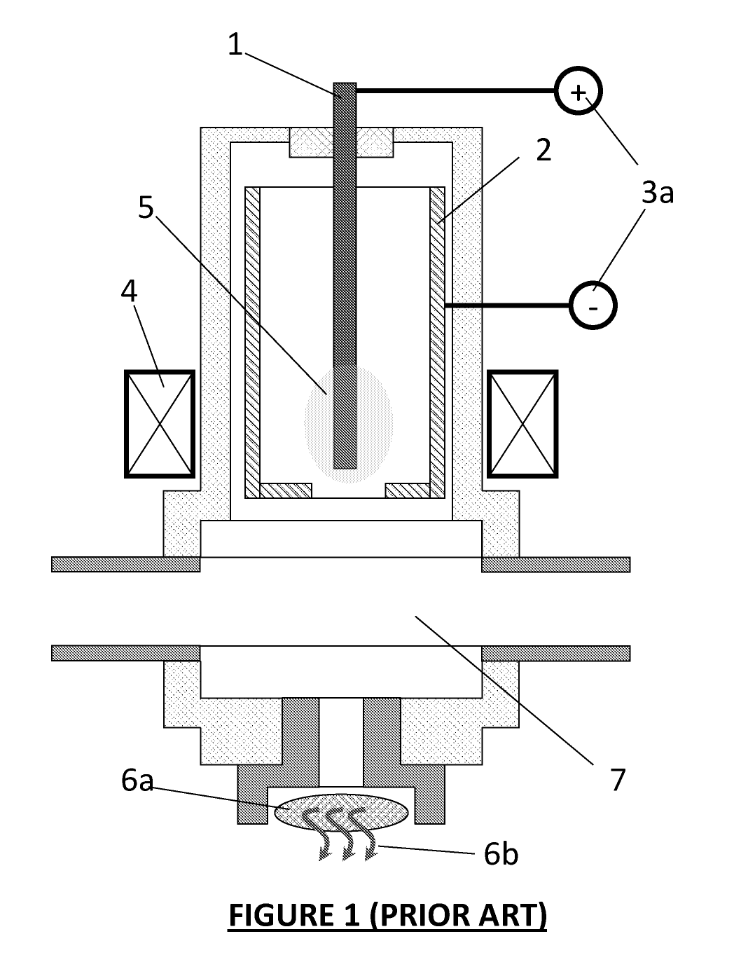

Referring now to the drawings: FIG. 1 shows a schematic of the previous art as described by GB2441582 where a plasma discharge 5 is generated by a suitable DC electrical polarisation 3a between electrodes 1 and 2. A suitable magnetic field created by magnetic elements 4 will aid the plasma confinement. Plasma emission is collected and guided via components 6a-6b towards suitable spectroscopic analysis elements such as photomultiplier tubes, CCD spectrometers, photodiodes or any other suitable optical device. The device would typically be connected to a sub-atmospheric pressure region 7. Different types of plasma discharge 5 would be attained depending on pressure conditions.

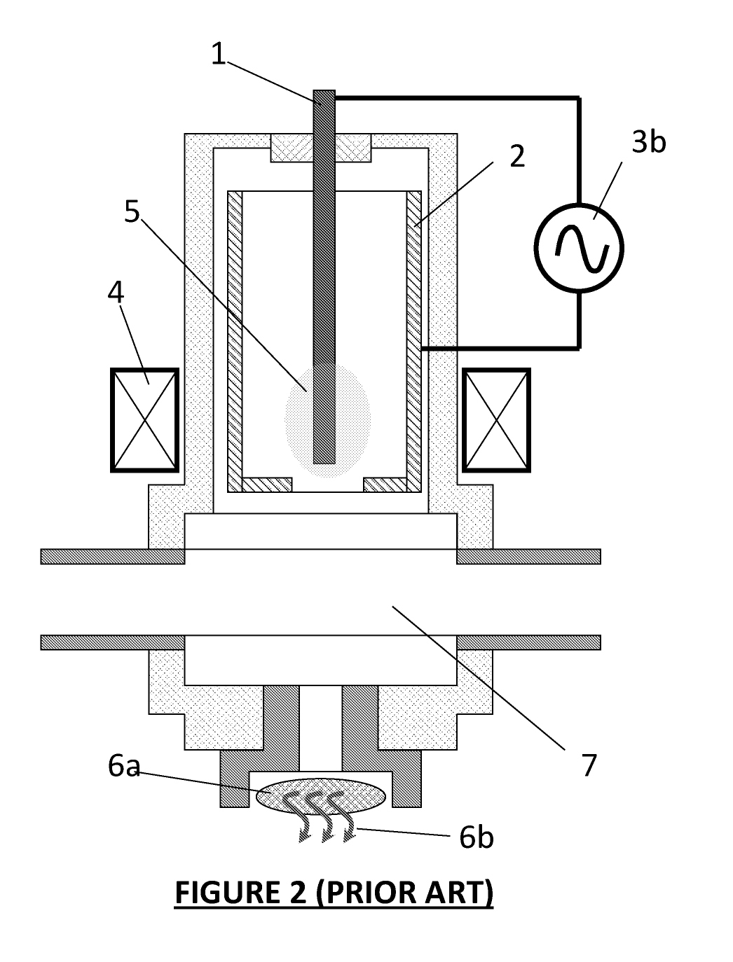

FIG. 2 shows a schematic of the previous art as described by GB2441582 where a plasma discharge 5 is generated by a suitable AC electrical polarisation 3b between electrodes 1 and 2. A suitable magnetic field created by magnetic elements 4 will aid the plasma confinement. In some embodiments of the present invention there would be no need for those magnetic elements 4 to be present. Plasma emission is collected and guided via components 6a-6b towards suitable spectroscopic analysis elements such as photomultiplier tubes, CCD spectrometers, photodiodes or any other suitable optical device. The device would typically be connected to a sub-atmospheric pressure region 7. Different types plasma discharge 5 would be attained depending on pressure conditions.

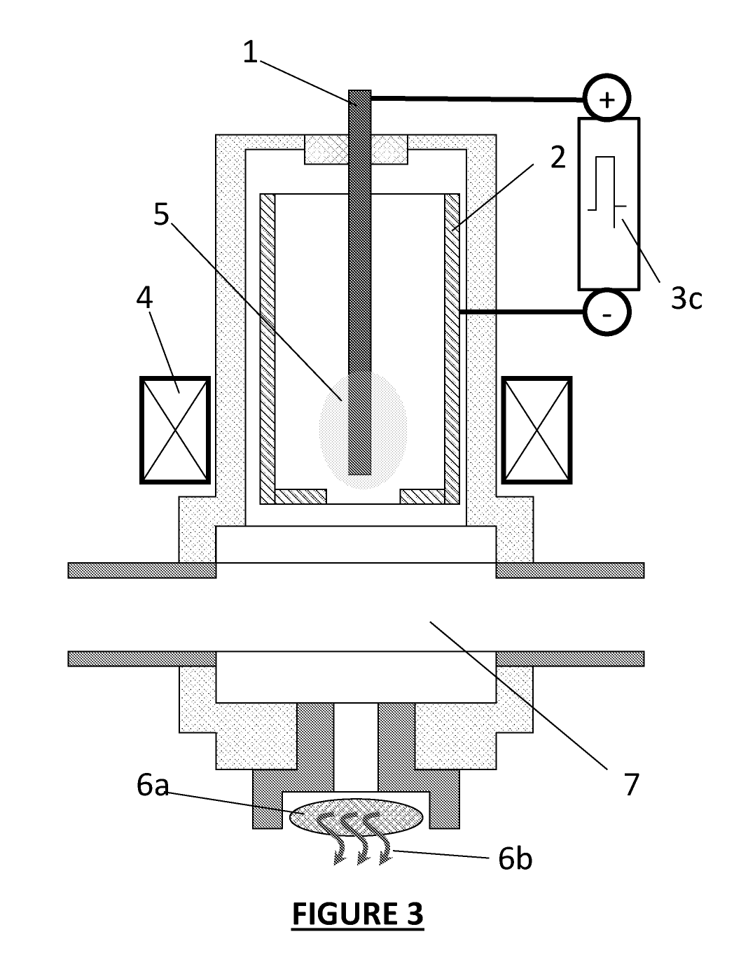

FIG. 3 shows a schematic embodiment of the present invention, where a plasma discharge 5 is generated by a suitable DC pulsed electrical polarisation 3c between electrodes 1 and 2, being electrode 1 substantially positive over electrode 2. A suitable magnetic field created by magnetic elements 4 will aid the plasma confinement. The transient pulsed discharge will induce an electrical field which will accelerate the ions of the plasma 5 towards the walls of the electrode 2. By controlling the electrical field and the pulsed conditions of 3c the energy of impact of the ions will be controlled, making sputtering of the wall of the electrode 2 possible. The plasma itself will contain not only the elements of the gas input or background but also the elements of the solid electrode 2. Plasma emission is collected and guided via components 6a-6b towards suitable spectroscopic analysis elements such as photomultiplier tubes, CCD spectrometers, photodiodes or any other suitable optical device. The device would typically be connected to a sub-atmospheric pressure region 7. Different types plasma discharge 5 would be attain depending on pressure conditions as well as the pulsed power condition.

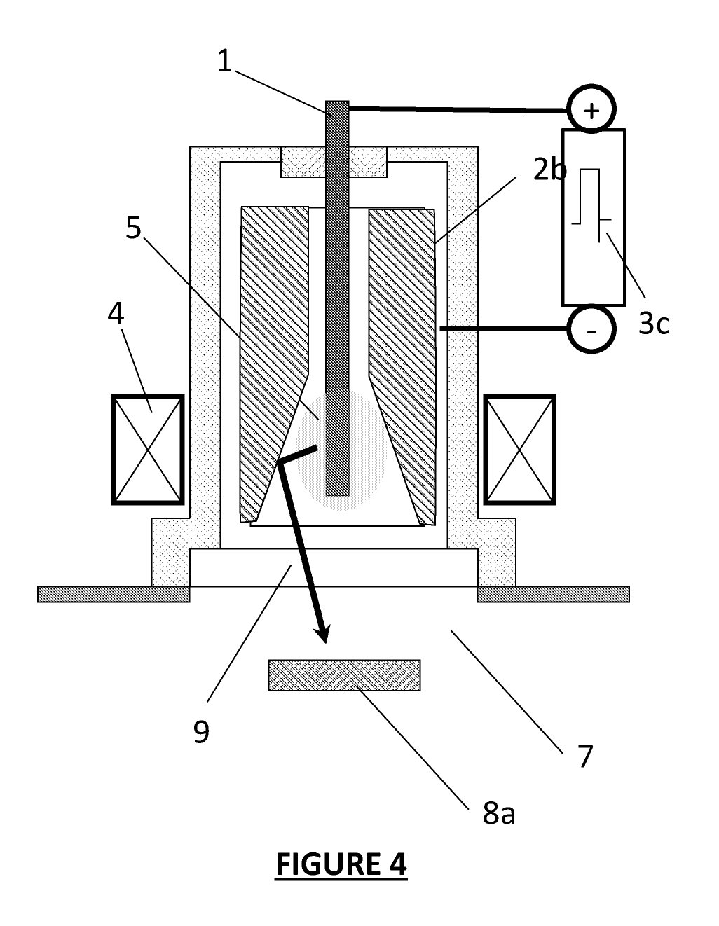

FIG. 4 shows a schematic embodiment of the present invention, where a plasma discharge 5 is generated by a suitable DC pulsed electrical polarisation 3c between electrodes 1 and 2b, being electrode 1 substantially positive over electrode 2b. A suitable magnetic field created by magnetic elements 4 will aid the plasma confinement. The transient pulsed discharge will induce an electrical field which will accelerate the ions of the plasma 5 towards the walls of the electrode 2b. By controlling the electrical field and the pulsed conditions of 3c the energy of impact of the ions will be controlled, making sputtering of the wall of the electrode 2b possible. The shape of the electrode 2b could be different. In the present embodiment the shape is such that would encourage sputtered material to escape the plasma zone towards the region 7 as indicated by impact particle trajectory 9. In this region 7 by placing a suitable substrate or component 8a, such component will receive coating material from electrode 2b. By controlling the gas mixture and the electrode 2b nature and the power discharge mode 3c and magnetic confinement it would be possible to use the ions generated by the device and escaping in trajectories such as 9 for different purposes, for example for ion etch of substrate 8a or for coating of substrate 8a.

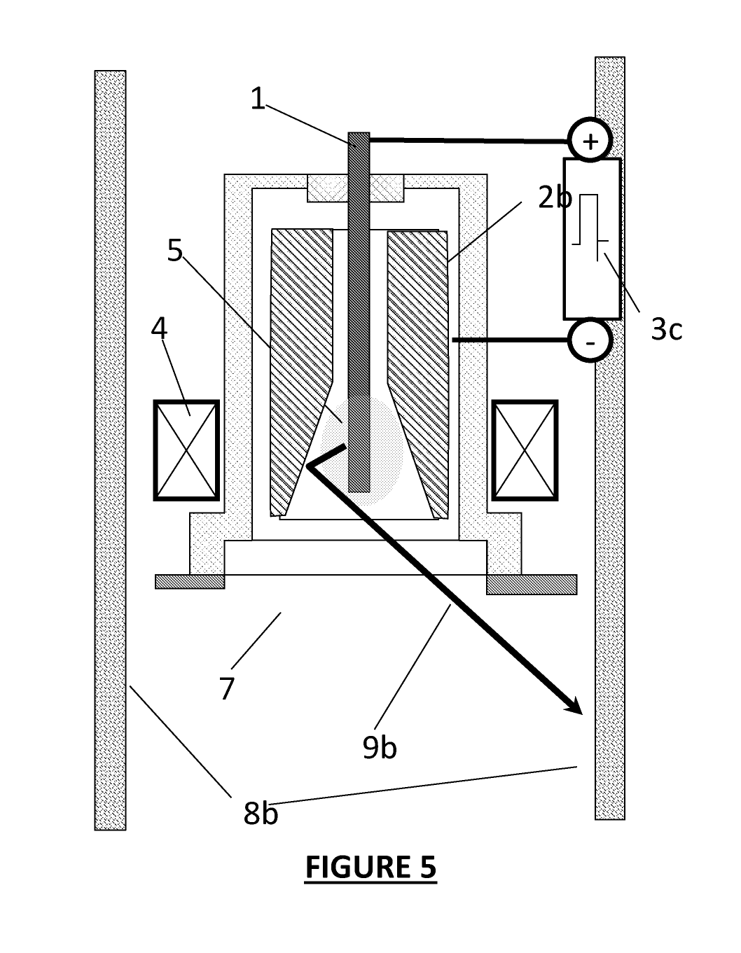

FIG. 5 shows a schematic embodiment and use of the present invention, where a plasma discharge 5 is generated by a suitable DC pulsed electrical polarisation 3c between electrodes 1 and 2b, being electrode 1 substantially positive over electrode 2b. A suitable magnetic field created by magnetic elements 4 will aid the plasma confinement. The transient pulsed discharge will induce an electrical field which will accelerate the ions of the plasma 5 towards the walls of the electrode 2b. By controlling the electrical field and the pulsed conditions of 3c the energy of impact of the ions will be controlled, making sputtering of the wall of the electrode 2b possible. The shape of the electrode 2b could be different. In the present embodiment the shape is such that would encourage sputtered material or ions to escape the plasma zone towards the region 7 as indicated by impact particle trajectory 9b. In this application the present invention will be able to plasma treat, ion bombard and coat the internal surface of a tube or internal section component 8b. By controlling the gas mixture and the electrode 2b nature and the power discharge mode 3c and magnetic confinement it would be possible to use the ions generated by the device and escaping in trajectories such as 9b for different purposes, including, although not exclusively, for ion etch of substrate 8b or for coating of substrate 8b.

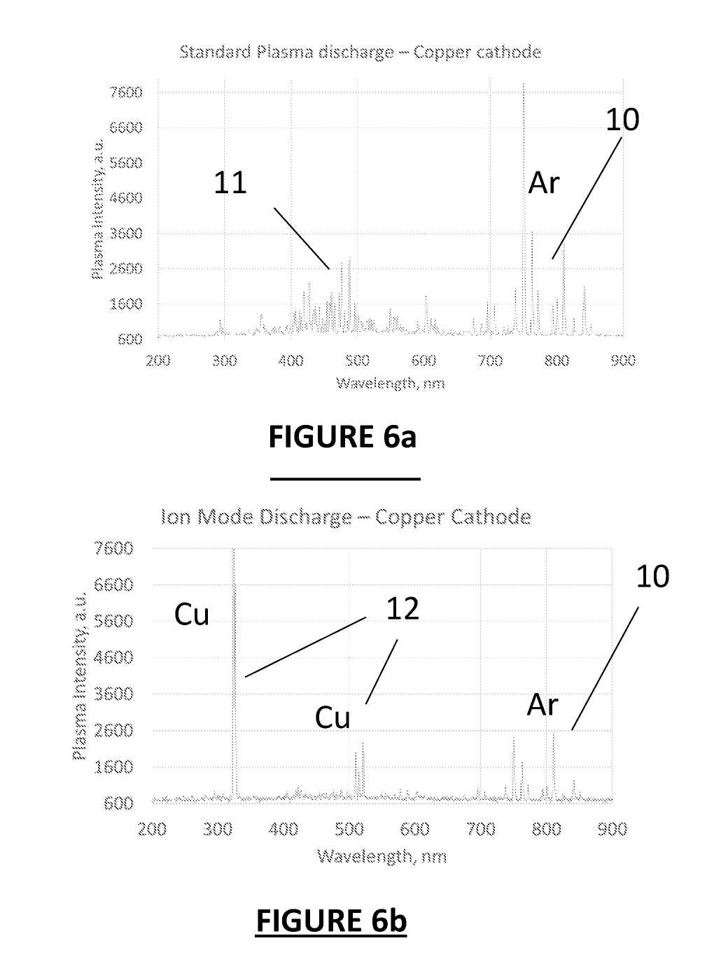

FIG. 6a shows an example of a CCD spectra of the plasma 5 when the discharge is made by means of the state of the art, as described in FIG. 1 and FIG. 2. The typical discharge shows two distinctive plasma emissions areas, 10 and 11. Emissions 10 correspond to non-ionised Ar. Emissions 11 form a complex emission pattern which would include some ionised Ar(+). Both emissions represent elements of the gas phase, usually Ar. The electrode material of 2, in the present example this was copper, however no emissions of copper could be seen in the spectra which would imply that no ion sputtering is taking place on the electrode 2.

FIG. 6b, shows an example of a CCD spectra of the plasma 5 when the discharge is made by means of the present invention as described by FIGS. 3,4 and 5. The typical discharge shows two distinctive plasma emissions areas, 10 and 12. Emissions 10 correspond to non-ionised Ar from the gas phase. However, emissions 12 corresponds to the element of the electrode material of 2 or 2b, in the present example this was copper. This would imply that there is ion sputtering of the electrode 2 or 2b taking place when using the current invention.

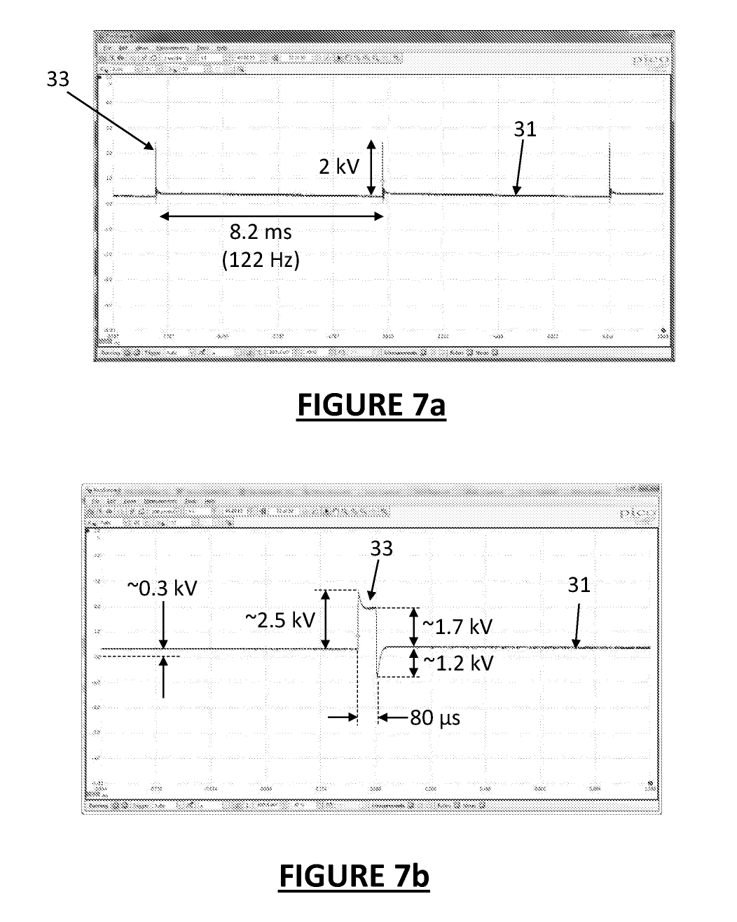

FIG. 7a, shows an oscilloscope voltage trace of a particular pulsed power 33 and frequency applied to the device of this invention. In this particular example the pulse 33 has a peak voltage of 2 kV while the frequency of pulse repetition is 122 Hz. The time on of the pulse could also be varied as well as the frequency and the energy of the pulse 33.

FIG. 7b, shows a close-up view of the oscilloscope voltage trace of FIG. 71, showing a particular power regime comprising a substantially constant baseline DC voltage 31 of approximately 0.3 kV in this example, which has superimposed upon it, a regular sequence of power pulses 33. In this particular example the pulse 33 has a nominal peak voltage of 2 kV (disregarding the overshoot of 2.5 kV at its leading edge) while the time on of the pulse is 80 μs. The pulse 33 could vary in power, voltage and current, from pulse to pulse depending on the dynamic plasma discharge conditions although, on-average it could also be considered relatively constant. The pulse 33 will be repeated at a frequency, which could also be varied or constant.

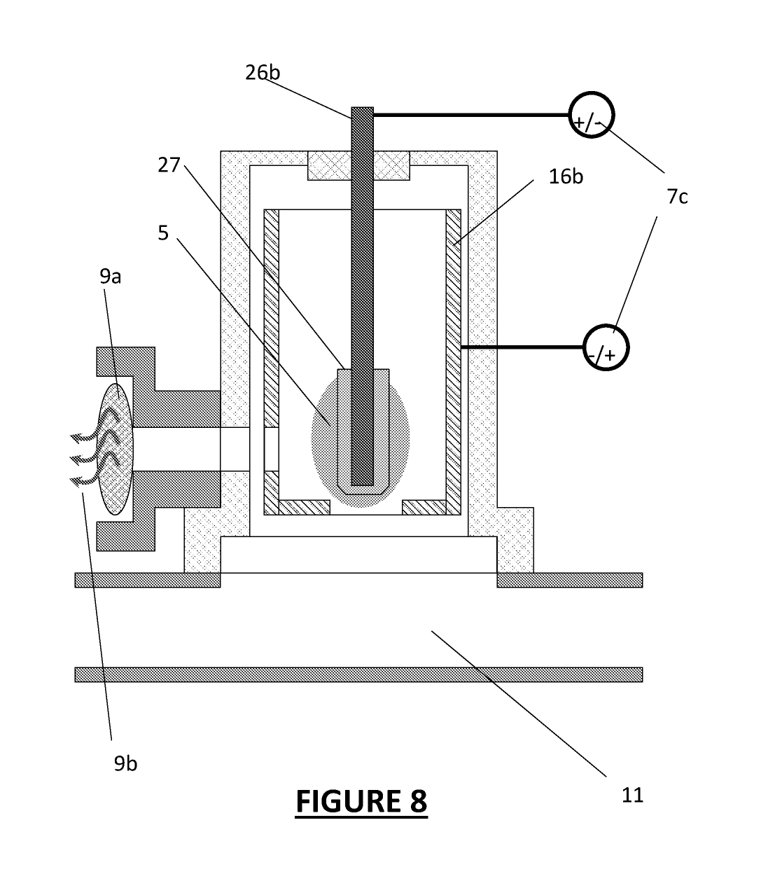

FIG. 8 shows a cross-section of a sensor embodiment as described by the present invention where a jacket 27 covers electrode 26b.

Plasma discharge 5 is generated by a suitable electrical polarisation 7c between electrodes 26b and 16b. The chemical/material composition of the jacket 27 would produce, in the presence of plasma 5, an emission containing element emissions of that material. However, by selecting suitable chemical elements with respect to the process that needs monitoring, the plasma emission of those elements would give information related to the main plasma or process. These elements are sensor markers.

For example, by using a Cr jacket 27, the preferential reactivity of Cr with respect to the main process would give an indirect control sensor signal, e.g., oxide, nitride, carbide deposition processes.

In another example, the sensor marker element could be helium, which could be injected, as a gas, in the locality of the sensor. The excitation emissions of helium are in competition with other elements and would serve as a marker amplifying the sensitivity of the detection of the other elements.

Plasma emission is collected and guided via components 9a-9b towards suitable spectroscopic analysis elements such as photomultiplier tubes, CCD spectrometers, photodiodes or any other suitable optical device.

The location of the sensor device 11 is typically remote, but still connected to the main process area. In the illustrated embodiment, the location of the plasma emission collection is in a substantially right angle orientation with respect to the electrode 26b although any other orientation is also possible as long as a plasma view is attainable.

A suitable clear view is needed via the device, for example via electrode 16b so that the spectral light can pass through towards optical elements 9a. The discharge plasma polarization could involve DC, DC Pulsed and any suitable AC excitation frequency from 10 KHz to 10 GHz.

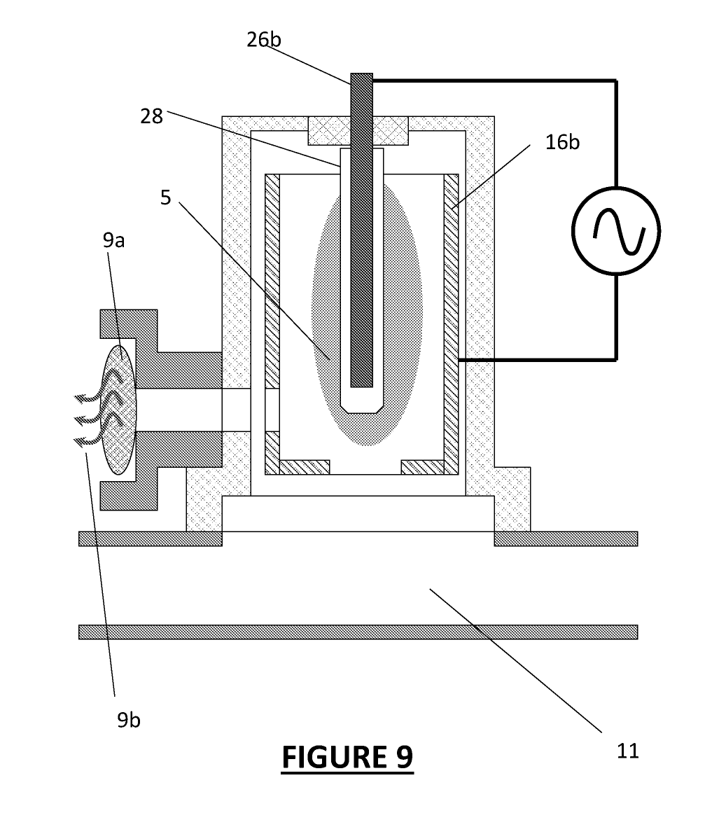

FIG. 9 shows a cross-section of a sensor embodiment as described by the present invention where a jacket sheath 28 covers electrode 26b. Plasma discharge 5 is generated by a suitable electrical polarisation 7d between electrodes 26b and 16b.

Sheath 28 is a barrier for plasma so that it is prevented from reaching electrode 26b. By selecting the elements from which the sheath is made and/or a suitable gas element, such as helium, the plasma 5 emission will serve to amplify the detection limits of other elements of the main plasma or system process.

Plasma emissions are collected and guided via components 9a-9b towards suitable spectroscopic analysis elements such as photomultiplier tubes, CCD spectrometers, photodiodes or any other suitable optical device.

Again, the location of the sensor device 11 is typically remote but still connected to the main process area. Location of the plasma emission collection could be in a substantially right angle orientation with respect to the electrode 26b, as in this figure, although any other orientation is also possible as long as a plasma view is attainable.

Again, a suitable clear view is needed via the device, for example via electrode 16b so that the spectral light can pass through towards optical elements 9a. The discharge plasma polarization could involve generally high frequency wave signal, generally AC with excitation frequency from 10 KHz to 10 GHz.

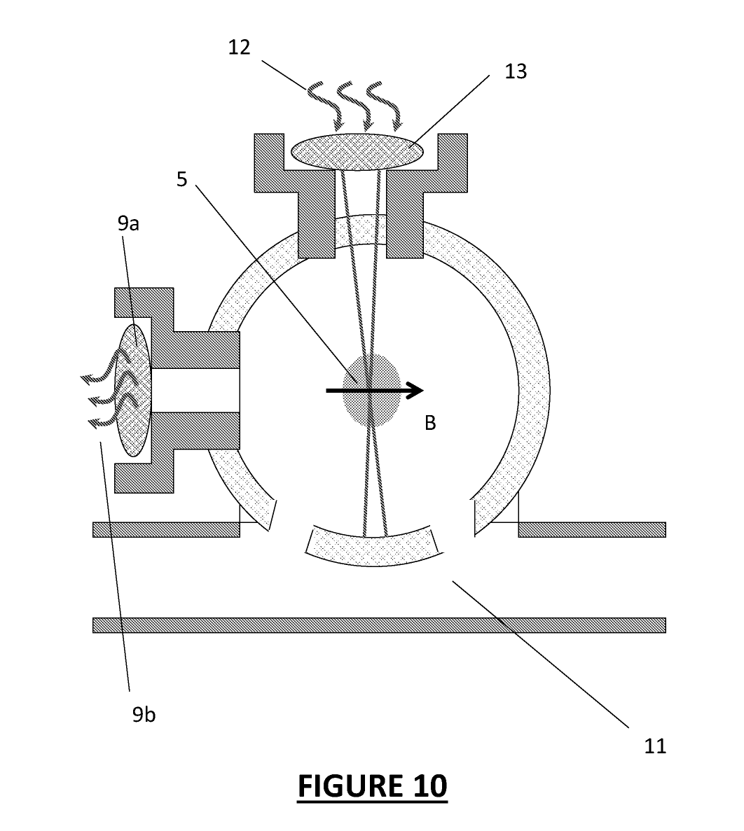

FIG. 10 shows a cross-section of another embodiment of the present invention. In this embodiment, the excitation is produced via an electromagnetic wave 12 such as a light source, for example a laser device in the UV/VIS/NIR region, or a microwave guided wave in the GHz region.

A suitable window 13 provides a pass through for the wave from the atmosphere into the vacuum side of the sensor, and it could also provide a focal point for the wave.

The presence of a magnetic field could also help to the confinement of the secondary plasma 5. The discharge mechanism could vary, for example it could be based on the cyclotron resonance of the electrons at a particular magnetic field strength and electromagnetic wavelength., The response signal can be collected by element 9a and the signal 9b can be carried towards the appropriate instrumentation. This particular device would be suitable for fluorescent emissions and for spectral information from the Infrared (IR) and Near-infrared (NIR) region. Also other regions of signal could be used such as Visible (VIS) and Ultra-Violet (UV).

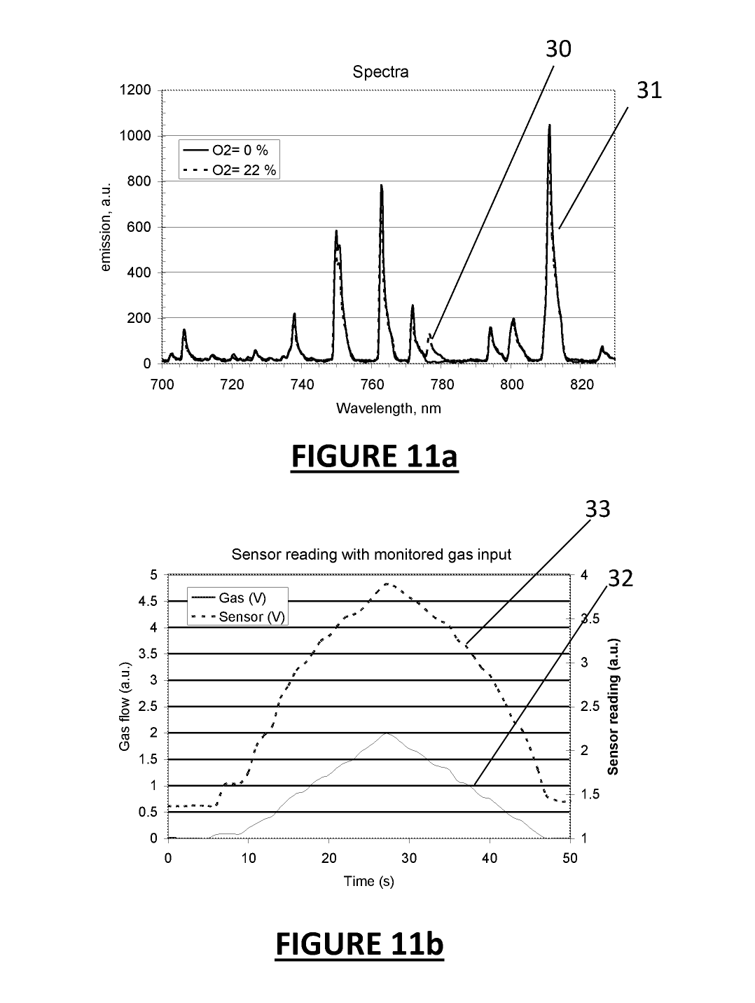

FIG. 11a shows an example of spectra that can be generated by a device from the present invention. The plasma emission contains gas lines such as those of Ar 31. In the presence of another gas, such as O2, the spectrum changes, and new plasma emissions can appear such as in 30 where a 777nm belonging to oxygen, can be seen. This emission can be used for monitoring and controlling purposes. In this way, as indicated in FIG. 11b, the gas actuation input 32 will result on a sensor signal variation 33.

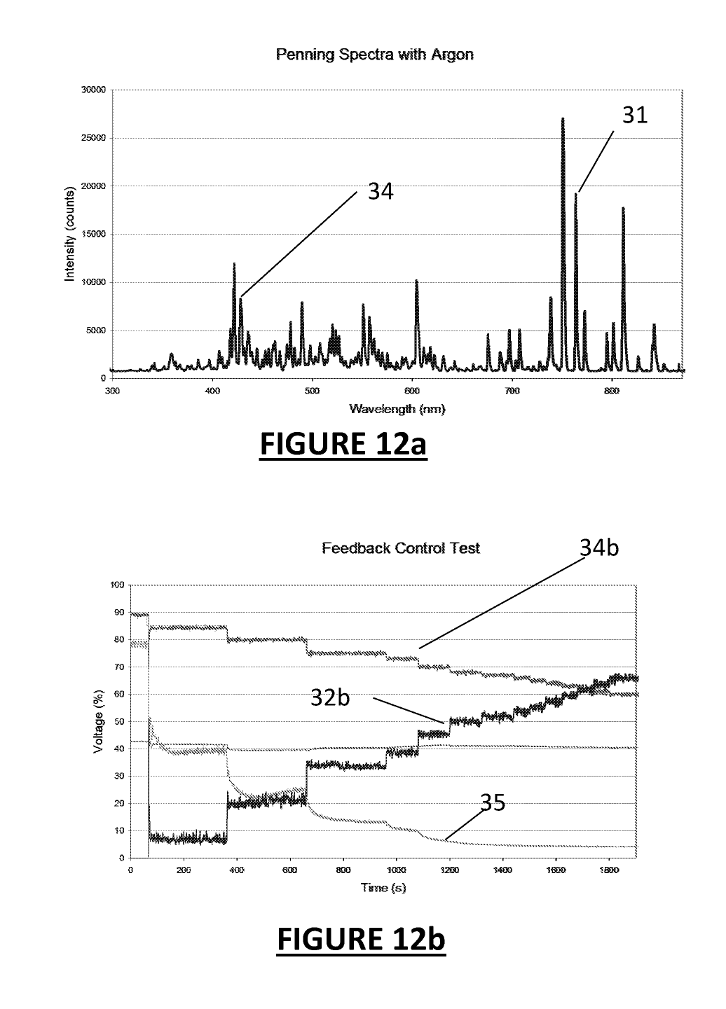

FIG. 12a, shows an example of spectra where in addition to gas lines 31, some metal emission lines from a jacket such as that described in FIG. 5 can be seen. By monitoring a suitable line, for example a 420 nm line on the example of FIG. 12b, the reactive gas input 32b can be modulated or controlled in order to control the Plasma emission setpoints 34b for the sensor plasma emission of the jacket element.

The primary plasma or process can be controlled. FIG. 12b also shows the evolution of one of the voltage primary sensors 35 present in the main process. Secondary plasma process is connected to the main process and in so the main process can be controlled via sensors on the secondary plasma.

It will be appreciated that the invention has been described by way of example only with reference to schematic diagrams and that the precise configuration and arrangement of the components can be altered without materially departing from the scope of this disclosure, which is defined by the claims. It will also be appreciated that the drawings accompanying this disclosure are schematic in nature and that, for example, where a magnet has been indicated, this could be an electromagnet or a permanent magnet, or a combination of the two. The same is true also for other illustrated features, such as the shape and configuration of the counter-electrode, the substrate to be coated etc. and it will be appreciated that a particular system may need to be adapted to meet specific user requirements.

1-54. (canceled)

55. An ion source comprising:
an electrode;
a counter electrode;
means for generating an electrical potential between the electrode and counter-electrode;
one or more magnets arranged, in use, to confine a plasma generated around the electrode upon application of the said electrical potential; and
an aperture in the counter-electrode through which ions from the said plasma can escape;
characterized in that: the means for generating an electrical potential between the electrode and counter electrode comprises a DC signal generator that is:
electrically connected to the electrode and the counter-electrode;
adapted, in use, to apply a baseline DC potential to the electrode and the counter-electrode with the DC potential at the electrode being positive relative to the DC potential at the counter electrode; and
adapted, in use, to apply a sequence of DC pulses superimposed onto the baseline DC potential, the power of each pulse varying in at least one of voltage and current from pulse to pulse.

56. The ion source of claim 55, wherein the DC pulse maximum potential, periodicity and duration are varied from pulse-to-pulse, or according to a predetermined change from one set of parameters to another.

57. The ion source of claim 55, wherein the baseline DC potential is any one or more of the group consisting of: between 0 and 0.5 kV; and substantially 0.3 kV.

58. The ion source of claim 55, wherein the or each DC pulse comprises any one or more of the group consisting of:
a) a peak voltage of between 1 and 3 Kv;
b) a peak voltage of substantially 2 kV;
c) an overshoot at its leading or trailing edge, which overshoot increases the maxima of each respective pulse to up to 2.5 kV;
d) an overshoot at its leading or trailing edge, which overshoot decreases the minima of each respective pulse to as low as −1 kV;
e) a duration of less than 100 ms;
f) a duration of substantially 80 ms; and
g) being applied at 5-10 ms intervals; being applied at substantially 8.2 ms intervals (122 Hz).

59. The ion source of claim 55, wherein the sequence of DC pulses superimposed onto the baseline DC potential is any one more of the group consisting of:
a) a periodic sequence; and
b) a regular periodic sequence.

60. The ion source of claim 55, wherein the DC pulse maximum potential, periodicity and duration are substantially fixed, or constant on-average.

61. The ion source of claim 55, further comprising a feedback system configured to maintain the emissions of the ion source substantially constant, which is adapted, in use, to control the DC signal generator in response to the instantaneous performance of the ion source, the feedback system comprising a spectroscopic analysis element being any one or more of the group comprising: a photomultiplier tube; a CCD spectrometer; and a photodiode located downstream of the aperture, the spectroscopic analysis element being adapted, in use, to measure the optical properties of the plasma, the feedback system further comprising calculating means for calculating required changes to the parameters of the DC signal generator, and means for providing feedback input controls to adapt/control the parameters of the DC signal generator.

62. The ion source of claim 55, wherein the counter-electrode comprises any one or more of the group comprising:
a) a shape configured such that it encourages sputtered material or ions to escape via the aperture;
b) a shape configured such that it encourages sputtered material or ions to escape via the aperture;
c) a shape comprising an inclined surface configured such that it encourages sputtered material or ions to escape via the aperture;
d) a shape comprising an inclined surface configured such that it encourages sputtered material or ions to escape via the aperture, the inclined surface being configured to deflect the trajectories of ions or other sputtered material towards a substrate to coated or treated; and
e) a shape comprising an inclined surface configured such that it encourages sputtered material or ions to escape via the aperture, the inclined surface being configured to deflect the trajectories of ions or other sputtered material towards a substrate to coated or treated, which is located in-line with the aperture and in which the inclined surface is configured to deflect the trajectories of ions or other sputtered material radially outwardly to impinge on a substrate at least partially surrounding the ion source.

63. The ion source of claim 55, further comprising a sensor marker in the plasma zone, the plasma zone being the region surrounding the electrode in which the plasma is generated, the sensor marker producing, in the presence of the plasma, an emission containing emissions of that material.

64. The ion source of claim 55, wherein the sensor marker comprises any one or more of the group consisting of
a) a tube, at least partially surrounding the electrode, manufactured from a material of a specified element;
b) a rod or plate adjacent the electrode, manufactured from a material of a specified element; and
c) a gas, which gas is directed towards the electrode, the gas being a specified element that interacts with the plasma thereby increasing the sensitivity of the signal that is produced by elements that are present in the plasma.

65. The ion source of claim 55, further comprising any one or more of the group consisting of:
a) an optical sensor adapted, in use, to measure an optical characteristic of the plasma;
b) an optical sensor adapted, in use, to measure an optical characteristic of the plasma, the optical sensor comprising any one or more of the group comprising:
i) an infrared detector;
ii) a visible light detector;
iii) an ultraviolet detector;
iv) a spectroscopic detector;
c) and a spectroscopic detector configured, in use, to measure any one or more of the group comprising:
i) an emission spectrum of the plasma;
ii) an absorption spectrum of the plasma; and
iii) a fluorescence spectrum of the plasma.

66. A method of using an ion source comprising: an electrode; a counter electrode; a DC signal generator electrically connected to the electrode and the counter-electrode; one or more magnets arranged, in use, to confine, in use, a plasma generated around the electrode; and an aperture in the counter-electrode through which ions from the said plasma can escape; the method being characterized by the steps of:
generating a baseline electrical potential between the electrode and counter-electrode, with the DC potential at the electrode being positive relative to the DC potential at the counter electrode; and
applying a sequence of DC pulses superimposed onto the baseline DC potential, the power of each pulse varying in voltage and/or current from pulse to pulse.

67. The method of claim 66, comprising the steps of: measuring the optical properties of the plasma using any one or more of the group comprising: a photomultiplier tube; a CCD spectrometer; and a photodiode—located downstream of the aperture; calculating required changes to the parameters of the DC signal generator; and providing feedback input controls to adapt/control the parameters of the DC signal generator so as to control the DC signal generator in response to the instantaneous performance of the ion source.

68. The method of claim 66, comprising the step of maintaining the emissions of the ion source substantially constant.

69. The method of claim 66, comprising the step of moving the ion source within the interior of a hollow object to be coated/treated by the ion source.

70. The method of claim 69, comprising the step of axially advancing the ion source along the interior of a tubular substrate to be coated or treated.

71. The method of claim 66, comprising the step of locating the ion source in a least partially evacuated environment.

72. The method of claim 71, further comprising the step of introducing into the at least partially evacuated environment; an inert, catalytic or reactive gas.

73. The method of claim 66, further comprising the step of varying the DC pulse maximum potential, periodicity and duration from pulse-to-pulse, or according to a predetermined change from one set of parameters to another.

74. The method of claim 66 comprising the step of providing a baseline DC potential of any one or more of the group consisting of: between 0 and 0.5 kV; and substantially 0.3 kV; and providing DC pulses which comprise any one or more of the group consisting of:
a) a peak voltage of between 1 and 3 Kv;
b) a peak voltage of substantially 2 kV;
c) an overshoot at its leading or trailing edge, which overshoot increases the maxima of each respective pulse to up to 2.5 kV;
d) an overshoot at its leading or trailing edge, which overshoot decreases the minima of each respective pulse to as low as −1 kV;
e) a duration of less than 100 ms;
f) a duration of substantially 80 ms; and
g) being applied at 5-10 ms intervals; being applied at substantially 8.2 ms intervals (122 Hz).
